(19) United States
(12) Patent Application Publication
(10) Pub. No.: US 2026/0290447 A1
(43) Pub. Date: Sep. 24, 2026

(54) MEMORY DEVICE INCLUDING TERNARY MEMORY CELL

(71) Applicant: TERNELL CO., LTD., Ulsan (KR)

(72) Inventor: Myoung KIM, Seoul (KR)

(73) Assignee: TERNELL CO., LTD., Ulsan (KR)

(21) Appl. No.: 19/221,218

(22) Filed: May 28, 2025

(30) Foreign Application Priority Data
Mar. 20, 2025 (KR) 10-2025-0035709
Apr. 1, 2025 (KR) 10-2025-0041890

(51) Int. Cl. G11C 11/419; G11C 11/411; G11C 11/418

(52) U.S. Cl. CPC G11C 11/419; G11C 11/4113; G11C 11/418

(57) ABSTRACT

A memory device includes a memory cell array including at least two ternary memory cells, bit line peripheral circuitry configured to read 1st′ data corresponding to a voltage value of a bit line pair corresponding to first data stored in the memory cell array in a read mode and configured to write and store the first data corresponding to the 1st′ data corresponding to the voltage value of the bit line pair in the memory cell array in a write mode, and a code converter configured to receive the 1st′ data corresponding to the voltage value of the bit line pair and convert the 1st′ data into second data having a binary information system in the read mode and configured to receive the second data having the binary information system and convert the second data into the 1st′ data in the write mode.

### CROSS-REFERENCE TO RELATED APPLICATIONS

This application claims priority under 35 U.S.C. § 119 to Korean Patent Application No. 10-2025-0035709, filed on Mar. 20, 2025, and Korean Patent Application No. 10-2025-0041890, filed on Apr. 1, 2025, in the Korean Intellectual Property Office, the entire disclosures of which are hereby incorporated by reference herein in their entirety.

### BACKGROUND

The present disclosure relates to a memory device including a ternary memory cell.

High power consumption issues are occurring in processing of big data-centric tasks such as artificial intelligence (AI). To address this, memory allocation space inside semiconductor chips is gradually increasing. Static random access memory (SRAM), a representative memory included in a chip, has been closest to a central processing unit (CPU) in a memory hierarchy because SRAM can be simultaneously integrated with a processor and operates at high speed. However, with the recent increasing demand for processing of more data, structural changes in the entire memory hierarchy including level 1 (L1) cache are required.

In the memory hierarchy, the L1 cache has the least capacity and consumes low energy when accessed. However, from a latency perspective, L1 cache consumes 1.5 times more energy than level 3 (L3) cache while the storage capacity of the L1 cache is only 1/1,000 of that of the L3 cache. This leads to a decrease in the energy efficiency of high performance computing (HPC) chips. Therefore, it is very difficult to simultaneously optimize memory area and power consumption, and expensive process node expansion is essential to overcome this difficulty.

Therefore, there has been active research into simultaneously improving memory area and power consumption by utilizing ternary memory cells.

### SUMMARY

The present disclosure provides a memory device including a ternary memory cell that simultaneously improves memory area and power consumption.

However, these tasks are exemplary and the scope of the present disclosure is not limited thereby.

According to one aspect of the present disclosure, a memory device includes a memory cell array including at least two ternary memory cells each connected to a word line and a bit line pair including a bit line and an inverted bit line, the at least two ternary memory cells each storing first data having a ternary information system; bit line peripheral circuitry connected to each of the at least two ternary memory cells through the bit line pair, the bit line peripheral circuitry configured to read 1st′ data corresponding to a voltage value of the bit line pair corresponding to the first data stored in the memory cell array in a read mode and configured to write and store the first data corresponding to the 1st′ data corresponding to the voltage value of the bit line pair in the memory cell array in a write mode; and a code converter connected to the bit line peripheral circuitry, the code converter configured to receive the 1st′ data corresponding to the voltage value of the bit line pair from the bit line peripheral circuitry and convert the 1st′ data into second data having a binary information system in the read mode and configured to receive the second data, convert the second data into the 1st′ data corresponding to the voltage value of the bit line pair, and transmit the 1st′ data to the bit line peripheral circuitry in the write mode.

Here, the number of the at least two ternary memory cells, Mₜₑᵣ, may be a natural number satisfying

$${M}_{ter} = \frac{2}{3} * [ {2}^{n} + \{ 1 + \frac{1 + {( - 1 )}^{n}}{2} \} ]$$

with respect to the number of binary bits, “n”, of the second data.

Here, the bit line peripheral circuitry may include a bit line precharge circuit configured to precharge the bit line pair to an initial voltage in a standby mode.

Here, the bit line peripheral circuitry may include a read peripheral circuit configured to, in the read mode, read a state, in which the initial voltage of the bit line pair is maintained, or a state, in which the initial voltage of one of the bit line and the inverted bit line in the bit line pair is changed, according to the first data stored in a selected one of the at least two ternary memory cells and generate the 1st′ data corresponding to the voltage value of the bit line pair.

Here, the first data may correspond to one of a first logic value, a second logic value, and a third logic value. The first logic value may correspond to the state in which the initial voltage of one of the bit line and the inverted bit line in the bit line pair is changed. The second logic value may correspond to the state in which the initial voltage of the bit line pair is maintained. The third logic value may correspond to a state in which the initial voltage of the other one of the bit line and the inverted bit line in the bit line pair is changed.

Here, the 1st′ data may have one of a 1st′ logic value, a 2nd′ logic value, and a 3rd′ logic value. Each of the 1st′ logic value, the 2nd′ logic value, and the 3rd′ logic value may have the binary information system in correspondence to a change or maintenance of the initial voltage of the bit line pair.

Here, the bit line peripheral circuitry may include a write peripheral circuit configured to write the first data to a selected one of the at least two ternary memory cells in the write mode by maintaining the initial voltage of the bit line pair or changing the initial voltage of one of the bit line and the inverted bit line in the bit line pair, based on the 1st′ data received from the code converter.

Here, the first data may have one of a first logic value, a second logic value, and a third logic value. The first logic value may correspond to the state in which the initial voltage of one of the bit line and the inverted bit line in the bit line pair is changed. The second logic value may correspond to the state in which the bit line pair is maintained at a precharge voltage. The third logic value may correspond to a state in which the initial voltage of the other one of the bit line and the inverted bit line in the bit line pair is changed.

Here, the 1st′ data may have one of a 1st′ logic value, a 2nd′ logic value, and a 3rd′ logic value. Each of the 1st′ logic value, the 2nd′ logic value, and the 3rd′ logic value may have the binary information system in correspondence to a change or maintenance of the initial voltage of the bit line pair.

Here, each of the at least two ternary memory cells may include a first inverter and a second inverter cross-connected to a first node and a second node and respectively including a P-channel transistor and an N-channel transistor, the first node having a voltage corresponding to the first data, and the second node having an inverted voltage of the voltage of the first node or a same voltage as the first node; a first access transistor having an end connected to the first node, an opposite end connected to one of the bit line and the inverted bit line in the bit line pair, and a control terminal connected to the word line; and a second access transistor having an end connected to the second node, an opposite end connected to the other one of the bit line and the inverted bit line in the bit line pair, and a control terminal connected to the word line.

Here, each of the at least two ternary memory cells may further include a first transistor having an end connected to a read-only word line, an opposite end connected to a read-only bit line, and a control terminal connected to the first node; and a second transistor having an end connected to the read-only word line, an opposite end connected to a read-only inverted bit line, and a control terminal connected to the second node.

Here, the memory device may further include an error correction code (ECC) encoder configured to generate ECC information to be stored together with the first data; and an ECC decoder configured to check for errors in the first data, based on the ECC information. In the write mode, the bit line peripheral circuitry may be further configured to store the ECC information when storing the first data in the memory cell array. In the read mode, the bit line peripheral circuitry may be further configured to transmit, to the ECC decoder, the ECC information included in the first data when reading the first data.

Here, the memory device may further include an input/output (I/O) interface configured to input or output the second data having the binary information system. The code converter may be further configured to transmit the second data to the I/O interface in the read mode and receive the second data from the I/O interface in the write mode.

Other aspects, features, and advantages than those described above will become apparent from the following drawings, claims, and detailed description.

### BRIEF DESCRIPTION OF THE DRAWINGS

These and/or other aspects will become apparent and more readily appreciated from the following description of the embodiments, taken in conjunction with the accompanying drawings in which:

FIG. 1 is a diagram illustrating a memory device according to an embodiment;

FIG. 2 is a circuit diagram showing an embodiment of a memory cell in FIG. 1;

FIG. 3 is a circuit diagram showing another embodiment of the memory cell in FIG. 1;

FIG. 4 is a diagram illustrating a memory device according to an embodiment of FIG. 1;

FIG. 5 is a flowchart illustrating a read mode operation of the memory device of FIG. 4;

FIG. 6 shows a logic table and a diagram each illustrating a read mode and a write mode of the memory device of FIG. 4 through examples of first data, 1st′ data, and second data;

FIG. 7 is a diagram illustrating an operation of reading 1st-1 data stored in a first memory cell in the flowchart of FIG. 5;

FIG. 8 is a diagram illustrating a read mode operation in the flowchart of FIG. 5;

FIG. 9 is a flowchart illustrating a write mode operation of the memory device of FIG. 4;

FIG. 10 is a diagram illustrating an operation in the write mode in the flowchart of FIG. 5;

FIG. 11 is a diagram illustrating an operation of writing 1st-1 data to a first memory cell in the flowchart of FIG. 9; and

FIG. 12 illustrates a memory device according to another embodiment.

### DETAILED DESCRIPTION

With respect to the terms used to describe the various embodiments, general terms which are currently and widely used are selected in consideration of functions of structural elements in the various embodiments of the present disclosure. However, meanings of the terms can be changed according to intention, a judicial precedence, the appearance of new technology, and the like. In addition, in certain cases, a term which is not commonly used can be selected. In such a case, the meaning of the term will be described in detail at the corresponding portion in the description of the present disclosure. Therefore, the terms used in the various embodiments of the present disclosure should be defined based on the meanings of the terms and the descriptions provided herein.

Unless otherwise defined, terms used herein have the same meaning as commonly understood by one of ordinary skill in the art to which the present disclosure belongs. It will be understood that terms, such as those defined in commonly used dictionaries, should be interpreted as having a meaning that is consistent with their meaning in the context of the relevant art, and will not be interpreted in an idealized or overly formal sense unless expressly so defined herein.

As embodiments allows for various changes and numerous embodiments, some embodiments will be illustrated in the drawings and described in detail in the written description. However, this is not intended to limit embodiments to particular modes of practice, and it is to be appreciated that all changes and substitutes that do not depart from the spirit and technical scope of the present disclosure are encompassed in embodiments. The terms used herein are used only to describe embodiments and are not intended to limit the embodiments.

The detailed descriptions below refer to the accompanying drawings which illustrate specific examples in which the disclosed technology may be implemented. These examples are described in sufficient detail to enable those skilled in the art to implement the disclosed technology. It should be understood that the various examples of the disclosed technology are different from each other but are not necessarily mutually exclusive. For example, specific shapes, structures, and characteristics described herein may be implemented as modified from one example to another without departing from the spirit and scope of the claimed subject matter. Furthermore, it should be understood that the locations or arrangements of individual elements within each of the examples may also be changed without departing from the spirit and scope of the claimed subject matter. Therefore, the detailed descriptions set forth below are not be taken in a limiting sense, and the scope of the claimed subject matter is to be taken as encompassing the scope of the appended claims and all equivalents thereof. In the drawings, like reference numerals denote identical or similar elements throughout several views.

While terms including ordinal numbers such as “first,” “second,” “1st-1,” “1st-2,” etc., may be used to describe various elements, such elements must not be limited to the above terms. The above terms are used only to distinguish one element from another.

It should be understood that when an element is referred to as being “connected” or “coupled” to another element, it can be directly connected or coupled to the other element or there may be other elements therebetween. In contrast, when an element is referred to as being “directly connected” or “directly coupled” to another element, it should be understood that there are no other elements therebetween.

In the various examples of the present disclosure described below, a hardware approach is described as an example. However, since various embodiments of the present disclosure may include techniques using both hardware and software, the various examples of the present disclosure do not exclude software-based approaches.

Hereinafter, various examples will be described in detail with reference to the accompanying drawings so as to be easily implemented by one of ordinary skill in the relevant art having the benefit of the present disclosure.

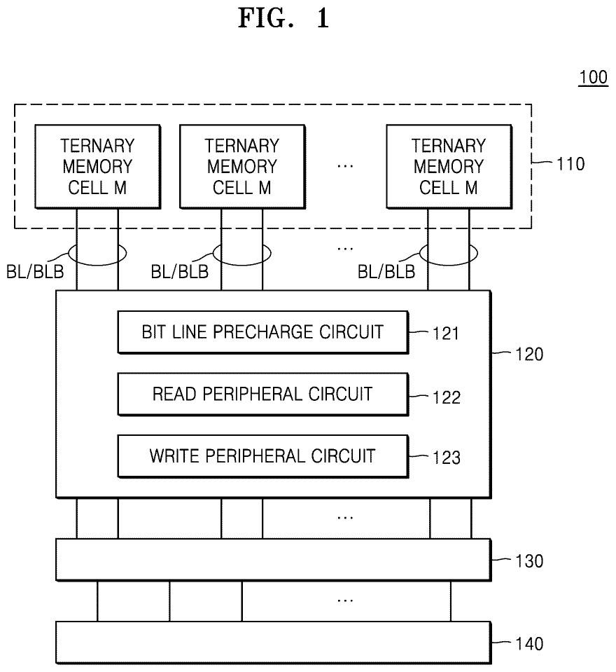

FIG. 1 is a diagram illustrating a memory device 100 according to an example of the disclosed technology.

Referring to FIG. 1, the memory device 100 may include a memory cell array 110 including at least two memory cells M, bit line peripheral circuitry 120, a code converter 130, and an input/output (I/O) interface 140.

A memory cell M may include a ternary memory cell. The memory cell M may have three different states and thus may store ternary logic values corresponding to the three different states. The memory cell M may store first data having a ternary information system. The first data may have first logical value “l”, second logical value “m”, and third logical value “h”.

For ternary memory cells, the ternary logic circuit proposed in Patent Publication No. 10-1689159 (hereinafter, referred to as “prior art”) may be utilized. For example, when a ground voltage (e.g., GND), a medium voltage (e.g., Vdd/2), and a positive supply voltage (e.g., Vdd) respectively corresponding to ternary logic values, i.e., logic values “l,” “m,” and “h” (or also expressed as logic values “0,” “1,” and “2”), are input to an inverter as a ternary logic circuit, the inverter may output the positive supply voltage (Vdd), the medium voltage (Vdd/2), and the ground voltage (GND) respectively corresponding to h/m/I logic values. Such a ternary logic circuit may provide an advantage of being able to process a larger amount of information than a general binary logic circuit, which uses the ground voltage (GND) and the positive supply voltage (Vdd) respectively corresponding to logic values “0” and “1”, and may also be advantageous in a logic-in-memory structure that output a value obtained by performing a logical operation on stored data.

Accordingly, the memory device 100 may include static random access memory (SRAM) and may include a ternary logic element or a ternary logic circuit proposed in the prior art. SRAM including memory cells M capable of storing ternary logic values may be referred to as ternary SRAM or T-SRAM.

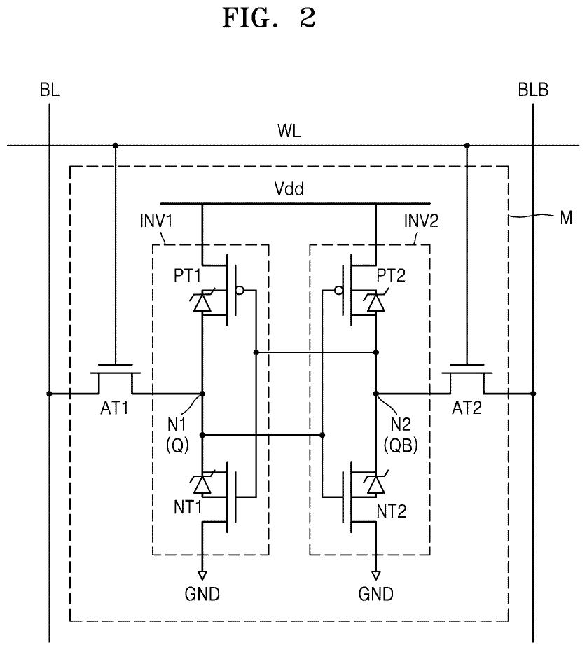

The memory cells M may be connected to a plurality of lines arranged in a matrix. Each of the memory cells M may be connected to a word line (e.g., WL in FIG. 2) extending in a row direction and a bit line pair BL/BLB extending in a column direction.

The word line may select and activate a specific memory cell M. The word line may activate all memory cells M in one row of the memory cell array 110 and connect a memory cell M in the row to the bit line pair BL/BLB, thereby enabling a data read operation or a data write operation.

The bit line pair BL/BLB may connect the bit line peripheral circuitry 120 to the memory cell M. The bit line pair BL/BLB may transmit data to the memory cell M, thereby allowing data stored in the memory cell M to be read during a read operation or data to be stored in the memory cell M during a write operation. The bit line pair BL/BLB may include a bit line BL and an inverted bit line BLB. The bit line BL may be the main path that transmits voltage when reading and writing data. The inverted bit line BLB may have a state that is opposite to or the same as the state of the bit line BL.

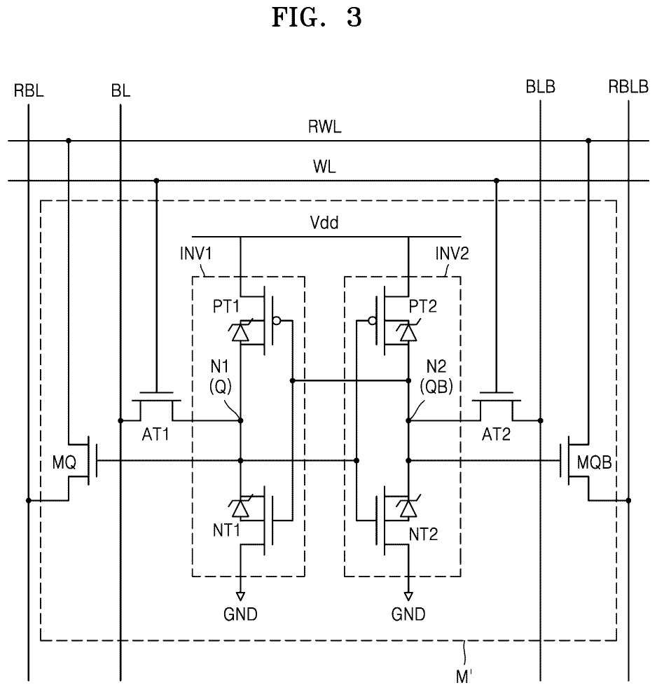

Specific examples of a memory cell M are described with reference to FIGS. 2 and 3.

FIG. 2 is a circuit diagram showing an example of the disclosed technology of the memory cell M in FIG. 1.

Referring to FIG. 2, the memory cell M may be connected to a word line WL and a bit line pair including a bit line BL and an inverted bit line BLB and may include a first inverter INV1, a second inverter INV2, a first access transistor AT1, and a second access transistor AT2.

The first inverter INV1 and the second inverter INV2 may be cross-connected to a first node N1 and a second node N2. Each of the first inverter INV1 and the second inverter INV2 may include a P-channel transistor and an N-channel transistor, which are configured to pass constant current when turned off. The P-channel transistor may have characteristics of a pull-up device, as disclosed in the prior art, and the N-channel transistor may have characteristics of a pull-down device as disclosed in the prior art.

The first inverter INV1 may include a first P-channel transistor PT1 and a first N-channel transistor NT1. The first P-channel transistor PT1 may have a gate connected to the second node N2, one end connected to a positive supply voltage Vdd, and the opposite end connected to the first N-channel transistor NT1. The first N-channel transistor NT1 may have a gate connected to the second node N2, one end connected to the first P-channel transistor PT1, and the opposite end connected to a ground voltage GND.

The second inverter INV2 may include a second P-channel transistor PT2 and a second N-channel transistor NT2. The second P-channel transistor PT2 may have a gate connected to the first node N1, one end connected to the positive supply voltage Vdd, and the opposite end connected to the second N-channel transistor NT2. The second N-channel transistor NT2 may have a gate connected to the first node N1, one end connected to the second P-channel transistor PT2, and the opposite end connected to the ground voltage GND.

Here, the first node N1 may be connected to the bit line BL by the first access transistor AT1, and the second node N2 may be connected to the inverted bit line BLB by the second access transistor AT2. The first node N1 and the second node N2 may read and write first data, and the voltages of the first node N1 and the second node N2 may indicate the storage state of the memory cell M. That is, the first node N1 and the second node N2 may have voltages corresponding to each logic value of the first data. The first node N1 may be referred to as a Q node, and the second node N2 may be referred to as a QB node. A voltage at the first node N1 may be referred to as a Q value, and a voltage at the second node N2 may be referred to as a QB value.

The first access transistor AT1 may be connected to the first node N1 and the bit line BL and may have a gate (or control terminal) connected to the word line WL. The first access transistor AT1 may electrically connect or disconnect the first node N1 to or from the bit line BL according to the voltage of the word line WL. For example, the first access transistor AT1 may include an N-channel field effect transistor (NFET). The first access transistor AT1 may electrically connect the first node N1 to the bit line BL in response to a voltage of the word line WL that is activated, i.e., at a high level, and electrically disconnect the first node N1 from the bit line BL in response to a voltage of the word line WL that is deactivated, i.e., at a low level.

Similar to the first access transistor AT1, the second access transistor AT2 may be connected to the second node N2 and the inverted bit line BLB and may have a gate (or control terminal) connected to the word line WL. In this specification, examples of the disclosed technology are described assuming that the first access transistor AT1 and the second access transistor AT2 are NFETs. However, it will be understood that aspects of the disclosed technology can also be applied to the case where the first access transistor AT1 and the second access transistor AT2 are P-channel FETs (PFETs), transmission gates, or the like.

The relationship between the operations of the first inverter INV1 and the second inverter INV2 and the first data stored in the memory cell M is briefly described. As described above, the first data may correspond to one of the first logic value “l”, the second logic value “m”, and the third logic value “h”. When the first node N1 is at the ground voltage GND (e.g., 0 V) and the second node N2 is at the positive supply voltage Vdd, it may be said that the voltage of the Q node is 0, the voltage of the QB node is Vdd, and the memory cell M stores the first logic value “l”. When the first node N1 and the second node N2 are at an medium voltage (e.g., Vdd/2), it may be said that the voltage of the Q node and the voltage of the QB node are Vdd/2 and the memory cell M stores the second logic value “m”. When the first node N1 is at the positive supply voltage Vdd and the second node N2 is at the ground voltage GND (e.g., 0 V), it may be said that the voltage of the Q node is Vdd, the voltage of the QB node is 0, and the memory cell M stores the third logic value “h”.

These are summarized in Table 1.

TABLE 1

| Voltage of Q node | Logic value of first data |
|---|---|
| 0 (0) | l |
| Vdd/2 (1/2) | m |
| Vdd (1) | h |

FIG. 3 is a circuit diagram showing another example of the memory cell in FIG. 1. Compared to FIG. 2, a memory cell M′ of FIG. 3 may further be connected to a read-only word line RWL, a read-only bit line RBL, and a read-only inverted bit line RBLB. Like the memory cell M of FIG. 2, the memory cell M′ of FIG. 3 may store one of ternary logic values.

The memory cell M′ of FIG. 3 may further include a first transistor MQ and a second transistor MQB in addition to the first inverter INV1, the second inverter INV2, the first access transistor AT1, and the second access transistor AT2 that have been described above. The descriptions of the first inverter INV1, the second inverter INV2, the first access transistor AT1, the second access transistor AT2, the first node N1, the second node N2, the Q node, and the QB node are the same as those of the memory cell M of FIG. 2, and therefore, the memory cell M of FIG. 2 is referred to for the descriptions thereof.

The first transistor MQ may have a gate connected to the first node N1, one end connected to the read-only word line RWL, and the opposite end connected to the read-only bit line RBL. The second transistor MQB may have a gate connected to the second node N2, one end connected to the read-only word line RWL, and the opposite end connected to the read-only inverted bit line RBLB.

Compared to the memory cell M of FIG. 2, the memory cell M′ of FIG. 3 may use separate signal lines for a write operation and a read operation, respectively, thereby preventing interference occurring during the write operation and enabling stable operation. It may contribute to reducing energy consumption of a read operation, especially in low-power memory design.

Referring back to FIG. 1, the memory cell array 110 may be connected to at least the bit line peripheral circuitry 120 through bit line pairs BL/BLB.

The bit line peripheral circuitry 120 may be connected to a ternary memory cell M through the bit line pair BL/BLB. The bit line peripheral circuitry 120 may write and store first data, which has a ternary information system, in the memory cell array 110 or read the stored first data, through the bit line pairs BL/BLB. In addition, the bit line peripheral circuitry 120 may write and store the first data corresponding to the voltage value of a bit line pair BL/BLB in the memory cell array 110 in a write mode and may read a voltage value of the bit line pair BL/BLB, which corresponds to the first data stored in the memory cell array 110, in a read mode.

The bit line peripheral circuitry 120 may include at least a bit line precharge circuit 121, a read peripheral circuit 122, and a write peripheral circuit 123.

The bit line precharge circuit 121 may precharge bit line pairs BL/BLBs to an initial voltage in a standby mode. Here, the standby mode may be a mode in which the memory cell M does not receive a specific read or write request so that power consumption is minimized. In the standby mode, a word line may be deactivated, and all bit line pairs BL/BLBs may be precharged to a constant initial voltage. For example, both the bit line BL and the inverted bit line BLB included in one bit line pair BL/BLB may be precharged to an initial voltage. In this specification, the initial voltage is expressed as Vdd having the same magnitude as the positive supply voltage but is not limited thereto. The initial voltage may be Vdd/2, which is half of the positive supply voltage, or a voltage having a different magnitude. The bit line precharge circuit 121 may set the bit line pairs BL/BLB to the initial voltage in response to the activation of a bit line precharge signal by a processor (not shown).

The read peripheral circuit 122 may read the first data stored in a selected memory cell M in the read mode. The read mode may be executed when a CPU or a controller, which is connected to the memory device 100, requests data from the memory device 100. The read peripheral circuit 122 may read a voltage value of the bit line pair BL/BLB, that is, a state in which the initial voltage of the bit line pair BL/BLB is maintained by the first data stored in the memory cell M selected in the read mode or a state in which the initial voltage of one of the bit line and the inverted bit line in the bit line pairs BL/BLB is changed based on the first data. The read peripheral circuit 122 may also generate 1st′ data corresponding to the voltage value of the read bit line pair BL/BLB.

Here, the 1st′ data may correspond to the voltage value of the bit line pair BL/BLB and may be a logic value of the bit line pair BL/BLB, which has a binary information system. That is, the logic value of the 1st′ data may have a binary information system in correspondence to the change or maintenance of the initial voltage of the bit line pair BL/BLB. Each bit line may have a binary information system of 0 and 1, and the bit line pair BL/BLB may express a ternary information system of (l, m, h) of the first data by using two pieces of binary information. For example, the 1st′ data may have one of a 1st′ logic value, a 2nd′ logic value, and a 3rd′ logic value. For example, the 1st′ logic value may refer to a state, in which the bit line BL is maintained at the initial voltage Vdd and the inverted bit line BLB is changed to the ground voltage GND, and may refer to (1 0) indicating that the bit line BL has a logic value “1” and the inverted bit line BLB has a logic value “0”. The 2nd′ logic value may refer to a state, in which both the bit line BL and the inverted bit line BLB are maintained at the initial voltage Vdd, and may refer to (1 1) indicating that the bit line BL has the logic value “1” and the inverted bit line BLB has the logic value “1”. The 3rd′ logic value may refer to a state, in which the bit line BL is changed to the ground voltage GND and the inverted bit line BLB is maintained at the initial voltage Vdd, and may refer to (0 1) indicating that the bit line BL has the logic value “0” and the inverted bit line BLB has the logic value “1”.

The first data and the 1st′ data may correspond to each other. As described above, since the first data may have the first logic value, the second logic value, or the third logic value, the 1st′ data may have the 1st′ logic value corresponding to the first logic value, the 2nd′ logic value corresponding to the second logic value, or the 3rd′ logic value corresponding to the third logic value.

This is summarized in Table 2.

TABLE 2

| | | | Logic value of 1st′ |
|---|---|---|---|
| Logic value of first data | BL | BLB | data |
| l (first logic value) | Vdd (1) | 0 (0) | 1 0 (1st′ logic value) |
| m (second logic value) | Vdd (1) | Vdd (1) | 1 1 (2nd′ logic value) |
| h (third logic value) | 0 (0) | Vdd (1) | 0 1 (3rd′ logic value) |

The write peripheral circuit 123 may store the first data in the selected memory cell M in the write mode. The write mode may be executed when a CPU or a controller, which is connected to the memory device 100, writes new data to the memory device 100. The write peripheral circuit 123 may maintain or change the initial voltage of the bit line pair BL/BLB connected to the selected memory cell M to write the first data to the selected memory cell M in the write mode. In detail, the write peripheral circuit 123 may maintain the initial voltage of the bit line pair BL/BLB or change the initial voltage of one of the bit line BL and the inverted bit line BLB in the bit line pairs (BL/BLB), based on the 1st′ data received from the code converter 130. Here, 1st′ data may be a logic value, which corresponds to second data, which has a binary information system and is input through the I/O interface 140, and is formed in a binary information system corresponding to the voltage value of the bit line pair BL/BLB. As described above, the logic value of the 1st′ data may have a binary information system corresponding to the change or maintenance of the initial voltage of the bit line pair BL/BLB and may correspond to a logic value of the first data. This is the same as the description of the read mode, and thus, redundant descriptions thereof are omitted.

Here, the second data may have a binary information system and may correspond to the first data, which has a ternary information system and is written to the memory cell M. Therefore, the second data, the 1st′ data, and the first data correspond to one another. According to an example of the disclosed technology, the memory device 100 may store the first data having a ternary information system while receiving or outputting data as the second data, which has a binary information system and corresponds to the first data. Therefore, according to an example, the memory device 100 may provide compatibility with a CPU, a controller, and other memory devices, which use a binary information system. For this purpose, according to an example, the memory device 100 may include the code converter 130.

Through the I/O interface 140, the second data may be input from another device to the memory device 100 or output from the memory device 100 to another device. The I/O interface 140 may include a buffer or a port. For example, the I/O interface 140 may include an I/O buffer that transmits data between a CPU or a controller and the memory device 100 and an I/O line that is a signal line for transmitting and receiving data.

The code converter 130 may be positioned between the bit line peripheral circuitry 120 and the I/O interface 140 and may convert the second data in a binary information system into the 1st′ data corresponding to the voltage value of the bit line pair BL/BLB. In detail, the code converter 130 may receive the 1st′ data corresponding to the voltage value of the bit line pair BL/BLB from the bit line peripheral circuitry 120 in the read mode, convert the 1st′ data into the second data, and transmit the second data to the I/O interface 140. The code converter 130 may also receive the second data from the I/O interface 140 in the write mode, convert the second data into the 1st′ data corresponding to the voltage value of the bit line pair BL/BLB, and transmit the 1st′ data to the bit line peripheral circuitry 120. The code converter 130 may convert 2ⁿ-bit information into 2ⁿ⁺¹/3-bit information or may convert 2ⁿ⁺¹/3-bit information into 2ⁿ-bit information. Here, the 2ⁿ-bit information may refer to information included in the second data, and the 2ⁿ⁺¹/3-bit information may refer to information included in the 1st′ data.

According to an example of the disclosed technology, the memory device 100 may have a smaller number of memory cells M compared to the number of binary bits of the second data. Ternary memory cells may have a 1.5-bit storage capacity compared to existing memory cells. This allows the same storage capacity to be expressed using fewer memory cells than 1-bit binary memory cells. Assuming the number of ternary memory cells is Mₜₑᵣ, Mₜₑᵣ required to store 2ⁿ-bit information may be defined as Equation 1.

$${M}_{ter} = \frac{2}{3} * [ {2}^{n} + \{ 1 + \frac{1 + {( - 1 )}^{n}}{2} \} ] \qquad Equation 1$$

Additionally, the number of bit line pairs, BLₚₐᵢᵣ, derived in proportion to Mₜₑᵣ may be expressed by Equation 2.

$${BL}_{pair} = \frac{4}{3} * [ {2}^{n} + \{ 1 + \frac{1 + {( - 1 )}^{n}}{2} \} ] \qquad Equation 2$$

When 2ⁿ-bit information is stored, 1.5 bits may be stored in each cell. Accordingly, 0.5 bits remain, and additional memory information Da is provided as follows.

$${D}_{a} = 1 + \frac{1 + {( - 1 )}^{n}}{2} \qquad Equation 3$$

According to an example of the disclosed technology, the memory device 100 may store the second data, which is input to or output from the memory device 100 and has a binary information system, in a ternary memory cell M as the first data having a ternary information system, thereby reducing the number of memory cells compared to a memory device composed of binary memory cells. According to an example, the memory device 100 may reduce the number of memory cells by about 33% compared to a typical memory device including binary memory cells, thereby reducing the area of the memory device 100 and providing high integration density and low power consumption.

Hereinafter, the operation of the memory device 100 is described using as an example a memory device including two ternary memory cells when the second data is constituted of three bits.

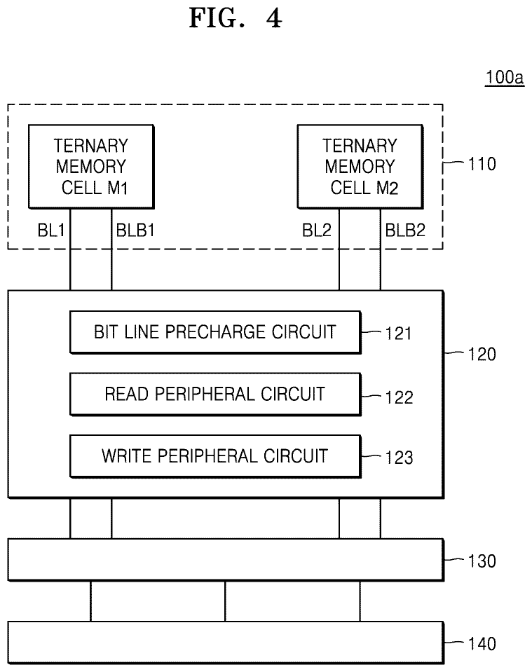

FIG. 4 is a diagram illustrating a memory device according to an example of FIG. 1.

Referring to FIG. 4, a memory device 100a may include the memory cell array 110 including two ternary memory cells, i.e., a first memory cell M1 and a second memory cell M2, the bit line peripheral circuitry 120, the code converter 130, and the I/O interface 140. Each of the first and second memory cells M1 and M2 in FIG. 4 may correspond to the memory cell M in the example of FIG. 2.

The first memory cell M1 may be connected to the word line WL (in FIG. 2) and a first bit line pair BL1/BLB1. The second memory cell M2 may be connected to the word line WL (in FIG. 2) and a second bit line pair BL2/BLB2. The first bit line pair BL1/BLB1 may include a first bit line BL1 and a first inverted bit line BLB1. The second bit line pair BL2/BLB2 may include a second bit line BL2 and a second inverted bit line BLB2.

The memory device 100a of FIG. 4 may process 3-bit second data. In the case of a memory device including binary memory cells, three binary memory cells are required to process the 3-bit second data. This is because each binary memory cell processes one bit. However, in the case of the memory device 100a of FIG. 4, only two ternary memory cells are sufficient to process the 3-bit second data. In this way, the memory device 100, 100a according to the certain examples may reduce the number of memory cells compared to binary memory devices according to the related art, thereby reducing the area of the memory device 100, 100a and providing high integration density and low power consumption.

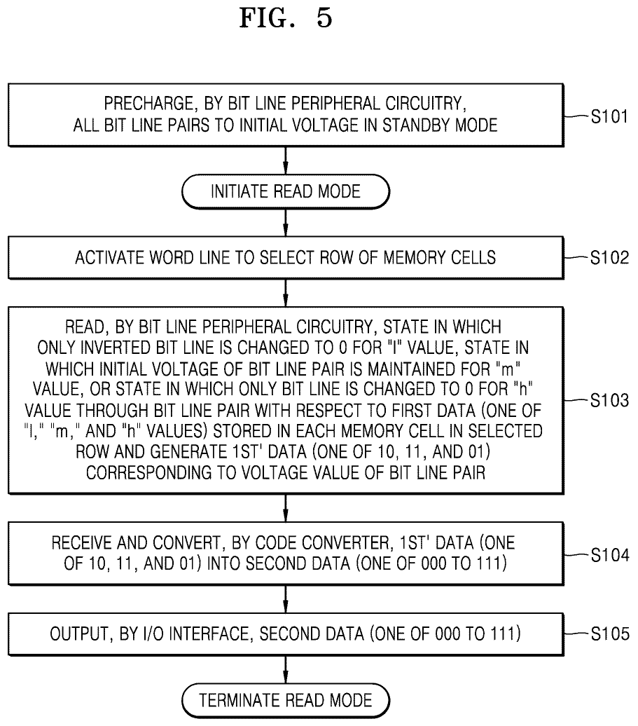

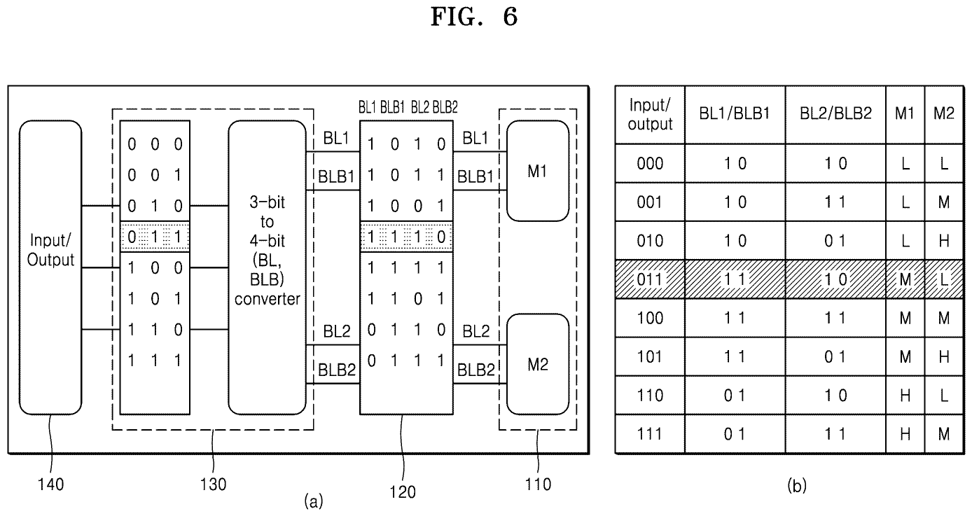

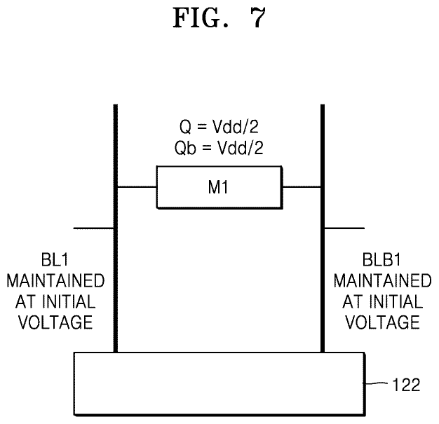

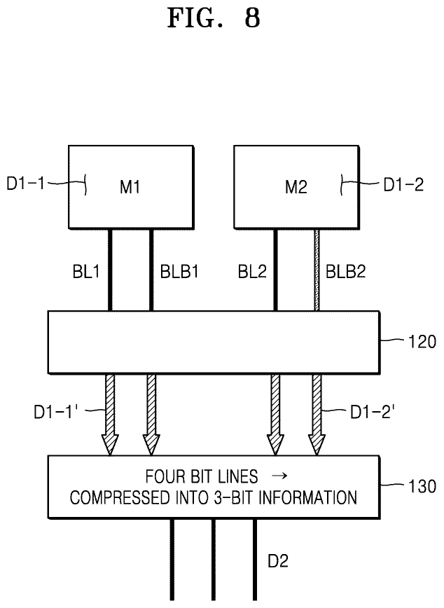

FIG. 5 is a flowchart illustrating a read mode operation of the memory device 100a of FIG. 4. FIG. 6 shows a logic table and a diagram each illustrating a read mode and a write mode of the memory device 100a of FIG. 4 through examples of the first data, the 1st′ data, and the second data. FIG. 7 is a diagram illustrating an operation of reading 1st-1 data stored in the first memory cell M1 in the flowchart of FIG. 5. FIG. 8 is a diagram illustrating a read mode operation in the flowchart of FIG. 5.

Referring to FIG. 5, the memory device 100a of FIG. 4 may perform an operation in which the bit line peripheral circuitry 120 pre-charges all bit line pairs to an initial voltage in the standby mode, an operation in which the read mode starts and a word line is activated to select a row including memory cells, an operation in which, with respect to the first data (one of “l,” “m,” and “h” values) stored in each of the memory cells in the selected row, one of a state in which only an inverted bit line is changed to 0 for the “l” value, a state in which the initial voltage of the bit line pairs is maintained for the “m” value, and a state in which only a bit line is changed to 0 for the “h” value, is read through a bit line pair connected to each memory cell and the 1st′ data (one of 10, 11, and 01) corresponding to a voltage value of the bit line pair is generate, an operation in which the code converter 130 receives the 1st′ data (one of 10, 11, and 01) and converts the 1st′ data into the second data (one of 000 to 111), and an operation in which the I/O interface 140 outputs the second data (one of 000 to 111) and terminates the read mode. Each operation may be performed by the memory device 100a. Because the memory device 100a includes a processor (not shown), each operation may also be considered as being performed by the processor.

In the read mode, it may be assumed that arbitrary first data (including the 1st-1 data and the 1st-2 data) is already stored in each memory cell (e.g., M1 or M2). In detail, it may be assumed that arbitrary 1st-1 data is stored in the first memory cell M1 and that arbitrary 1st-2 data is stored in the second memory cell M2. The first data (including the 1st-1 data and the 1st-2 data) may have a ternary information system.

Referring to FIGS. 4 and 5, the bit line peripheral circuitry 120 may precharge all bit line pairs (e.g., BL1/BLB1 and BL2/BLB2) to the initial voltage in the standby mode in operation S101. The initial voltage may be set to various values. The initial voltage may be set to Vdd that is the same as a positive supply voltage.

When the read mode is initiated, the word line may be activated, and the row including the first memory cell M1 and the second memory cell M2 may be selected, in operation S102. The word line may be connected to a row decoder. The row decoder may activate only one word line among a plurality of word lines according to an address received together with a command. Since only one row is shown in FIG. 4, the word line of the row including the first memory cell M1 and the second memory cell M2 may be activated.

Referring to FIGS. 5, 6, and 8, in operation S103, the bit line peripheral circuitry 120 may read the states of respective bit line pairs (BL1/BLB1 and BL2/BLB2) respectively corresponding to 1st-1 data (e.g., D1-1) stored in the first memory cell M1 and 1st-2 data (e.g., D1-2) stored in the second memory cell M2. The bit line peripheral circuitry 120 may also generate 1st-1′ data D1-1′ corresponding to the read state of the first bit line pair (BL1/BLB1) and 1st-2′ data D1-2′ corresponding to the read state of the second bit line pair (BL2/BLB2). Here, the combination of the 1st-1′ data and the 1st-2′ data may be considered as the 1st′ data described in FIG. 1.

The case where the logic value of the 1st-1 data stored in the first memory cell M1 is “m” and the logic value of the 1st-2 data stored in the second memory cell M2 is “l” in FIG. 6 is described as an example.

As described above, it may be assumed that the Q node value of the first memory cell M1 is Vdd/2 and that the 1st-1 data having the logic value “m” has already been stored in the first memory cell M1. In FIG. 6, when the logic value is “m”, the first bit line pair (BL1/BLB1) may be in a state in which the initial voltage of the standby mode is maintained. Therefore, the voltage value of the first bit line pair (BL1/BLB1) is Vdd that is the same as the initial voltage, and the bit line peripheral circuitry 120 may generate “1 1” as the 1st-1′ data corresponding to the voltage value of the first bit line pair (BL1/BLB1).

It may also be assumed that the Q node value of the second memory cell M2 is 0 and that the 1st-2 data having the logic value “l” has already been stored in the second memory cell M2. In FIG. 6, when the logic value is “l”, the second bit line pair (BL2/BLB2) corresponding to the logic value “l” may be in a state in which the second bit line BL2 is maintained at the initial voltage while the initial voltage of the second inverted bit line BLB2 is discharged to 0. Accordingly, the voltage value of the second bit line BL2 in the second bit line pair (BL2/BLB2) is Vdd, and the voltage value of the second inverted bit line BLB2 in the second bit line pair (BL2/BLB2) is 0. The bit line peripheral circuitry 120 may generates “10” as the 1st-2′ data corresponding to the voltage value of the second bit line pair (BL2/BLB2).

FIG. 7 schematically illustrates an operation in which the read peripheral circuit 122 reads the 1st-1 data stored in the first memory cell M1. According to an example of the disclosed technology, the memory device 100, 100a may use, as one data value in the read mode, a state in which a bit line pair is precharged to an initial voltage in the standby mode. In detail, according to an example, the memory device 100, 100a may set a state, in which a bit line pair maintains an initial voltage, to the logical value “m” that is additional information which is not used in a binary memory cell. Memory devices according to the related art do not use, as a data value in the read mode, a state precharged to the initial voltage in the standby mode. Memory devices according to the related art perform a read operation by unconditionally changing the voltage of a bit line pair in the read mode and thus consume about 10 times to about 1,000 times more energy in switching a latch and a buffer of the peripheral circuit than in the standby mode. However, in the case of the memory device 100, 100a according to an example, additional information may be expressed by using a state in which a bit line pair is precharged to an initial voltage so that energy efficiency may be improved and power consumption may be reduced compared to memory devices according to the related art.

Referring back to FIGS. 5, 6 and 8, in operation S104, the code converter 130 may receive the 1st-1′ data D1-1′ and the 1st-2′ data D1-2′ from the bit line peripheral circuitry 120 and may convert the combination of the 1st-1′ data D1-1′ and the 1st-2′ data D1-2′ into second data D2. That is, as shown in FIG. 8, the code converter 130 may compress pieces of information of respective four bit lines into 3-bit information.

The case where the logic value of the 1st-1 data stored in the first memory cell M1 is “m” and the logic value of the 1st-2 data stored in the second memory cell M2 is “l”, which is highlighted in FIG. 6, is described as an example.

The 1st-1′ data D1-1′ expressed as “11” generated in operation S103 and the 1st-2′ data D1-2′ expressed as “10” generated in operation S103 may be input to the code converter 130. The code converter 130 may convert a combination of the 1st-1′ data D1-1′ and the 1st-2′ data D1-2′ into the second data D2. In (b) of FIG. 6, pieces of the second data D2 are respectively mapped to possible combinations of the 1st-1′ data D1-1′ and the 1st-2′ data D1-2′. The mapping table of (b) of FIG. 6 is an example, and the code converter 130 may perform data conversion by using such mapping table.

Referring back to FIGS. 5, 6, and 8, the I/O interface 140 may output the second data D2 in operation S105.

According to the example of FIG. 6, the second data D2 expressed as “011” may be output by the read operation of the memory device 100a of FIG. 4, which includes the first memory cell M1 storing the logic value “m” and the second memory cell M2 storing the logic value “l”. That is, according to an example, the memory device 100 may output information, which is stored in the memory device 100 in a ternary information system, in a binary information system through a read operation.

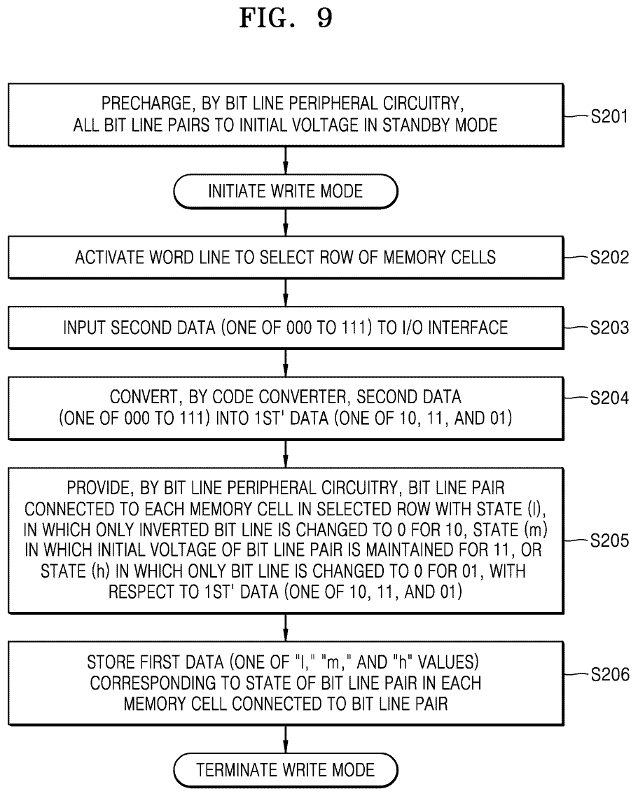

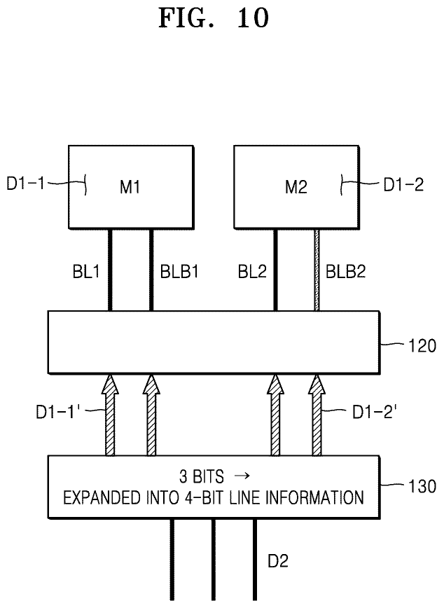

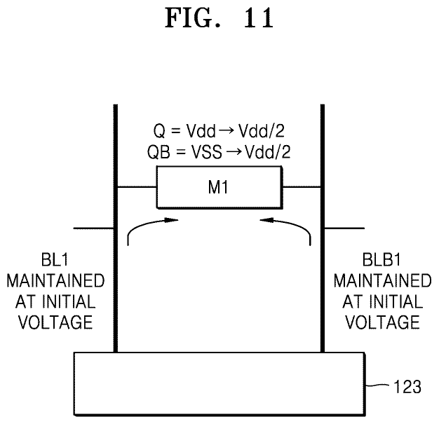

FIG. 9 is a flowchart illustrating a write mode operation of the memory device 100a of FIG. 4. FIG. 10 is a diagram illustrating the operation in the write mode in the flowchart of FIG. 5. FIG. 11 is a diagram illustrating an operation of writing the 1st-1 data to the first memory cell M1 in the flowchart of FIG. 9.

Referring to FIG. 9, the memory device 100a of FIG. 4 may perform an operation in which the bit line peripheral circuitry 120 precharges all bit line pairs to an initial voltage in the standby mode, an operation in which the write mode starts and a word line is activated to select a row including memory cells, an operation in which the second data (one of 000 to 111) is input to the I/O interface 140, an operation in which the code converter 130 converts the second data (one of 000 to 111) into the 1st′ data (one of 10, 11, and 01), an operation in which, with respect to the 1st′ data (one of 10, 11, and 01), the bit line peripheral circuitry 120 provides a bit line pair connected to each of the memory cells in the selected row with one of a state in which only an inverted bit line is changed to 0 with respect to 10, a state in which the initial voltage of the bit line pair is maintained with respect to 11, and a state in which only a bit line is changed to 0 with respect to 01, and an operation in which each memory cell in the selected row stores the first data (one of the logic value “l”, the logic value “m”, and the logic value “h”) which corresponds to the state of the bit line pair connected to each memory cell, and may terminate the write mode. Each operation may be performed by the memory device 100a. Because the memory device 100a includes a processor (not shown), each operation may also be considered as being performed by the processor.

Referring to FIGS. 4 and 9, the bit line peripheral circuitry 120 may precharge all bit line pairs to the initial voltage in the standby mode in operation S201. The initial voltage may be set to various values. The initial voltage may be set to Vdd that is the same as a positive supply voltage.

When the write mode is initiated, the word line (e.g., WL in FIG. 2) may be activated, and the row including the first memory cell M1 and the second memory cell M2 may be selected, in operation S202. The word line may be connected to a row decoder. The row decoder may activate only one word line among a plurality of word lines according to an address received together with a command. Since only one row is shown in FIG. 4, the word line of the row including the first memory cell M1 and the second memory cell M2 may be activated.

Referring to FIGS. 6, 9 and 10, the second data D2 having a binary information system may be input to the I/O interface 140 in operation S203.

An example of storing, in the memory device 100a, the second data expressed as 011 in FIG. 6 is described below as an example. For example, the second data may correspond to 3-bit information.

In operation S204, the code converter 130 may receive the second data D2 and convert the second data D2 into a corresponding combination of the 1st-1′ data D1-1′ and the 1st-2′ data D1-2′. In mapping table (b) of FIG. 6, a combination of the 1st-1′ data D1-1′ expressed as 11 and the 1st-2′ data D1-2′ expressed as 10 is mapped to a possible piece of the second data D2. The mapping table (b) of FIG. 6 is an example, and the code converter 130 may perform data conversion by using such mapping table. That is, as shown in FIG. 10, the code converter 130 may expand 3-bit information into pieces of information of respective four bit lines.

Referring back to FIGS. 6 and 9, in operation S205, the bit line peripheral circuitry 120 may provide a state of the first bit line pair (BL1/BLB1), which corresponds to the 1st-1′ data D1-1′, for the first bit line pair (BL1/BLB1) connected to the first memory cell M1 and a state of the second bit line pair (BL2/BLB2), which corresponds to the 1st-2′ data D1-2′ for the second bit line pair (BL2/BLB2) connected to the second memory cell M2.

Subsequently, in operation S206, the first memory cell M1 may write and store the 1st-1′ data D1-1′ corresponding to the state of the first bit line pair (BL1/BLB1), and the second memory cell M2 may write and store the 1st-2′ data D1-2′ corresponding to the state of the second bit line pair (BL2/BLB2), and then the write mode may be terminated.

The case where the 1st-1′ data D1-1′ is 11 and the 1st-2′ data D1-2′ is 10 in FIG. 6 is described below as an example.

As described above, the state of the first bit line pair (BL1/BLB1), which corresponds to the 1st-1′ data, may indicate that the initial voltage of the standby mode is maintained. Accordingly, the voltage value of the first bit line pair (BL1/BLB1) may be Vdd, which is the same as the initial voltage, and the bit line peripheral circuitry 120 may maintain the voltage value of the first bit line pair (BL1/BLB1) with respect to the 1st-1′ data of the first bit line pair (BL1/BLB1). In this case, the Q node value of the first memory cell M1 may be Vdd/2, and the QB node value may also be Vdd/2. Accordingly, the first memory cell M1 may write and store the 1st-1 data representing the logic value “m”, which corresponds to the Q node value and the QB node value.

The state of the second bit line pair (BL2/BLB2), which corresponds to the 1st-2′ data, may indicate that the second bit line BL2 is maintained at the initial voltage and that the initial voltage of the second inverted bit line BLB2 is discharged to 0. Accordingly, the voltage value of the second bit line BL2 in the second bit line pair (BL2/BLB2) may be Vdd, and the second inverted bit line (BLB2) in the second bit line pair (BL2/BLB2) may be 0. With respect to the 1st-2′ data of the second bit line pair (BL2/BLB2), the bit line peripheral circuitry 120 may maintain the voltage value of the second bit line BL2 and may change the voltage value of the second inverted bit line BLB2 into 0. In this case, the Q node value of the second memory cell M2 may be 0, and the QB node value of the second memory cell M2 may be Vdd, which is an inverted value of the Q node value. Accordingly, the second memory cell M2 may write and store the 1st-2 data representing the logic value “l”, which corresponds to the Q node value and the QB node value.

FIG. 11 illustrates an operation in which the write peripheral circuit 123 writes the 1st-1 data to the first memory cell M1. According to an example, the memory device 100 may use, as one data value in the write mode, a state in which a bit line pair is precharged to an initial voltage in the standby mode. In detail, according to an example, the memory device 100 may set a state, in which a bit line pair maintains an initial voltage, to the logical value “m” that is additional information which is not used in a binary memory cell. Memory devices according to the related art do not use, as a data value in the write mode, a state precharged to the initial voltage in the standby mode. Memory devices according to the related art perform a write operation by unconditionally changing the voltage of a bit line pair in the write mode and thus consume about 10 times to about 1,000 times more energy in switching a latch and a buffer of the peripheral circuit than in the standby mode. However, in the case of the memory device 100 according to an example, additional information may be expressed by using a state in which a bit line pair is precharged to an initial voltage so that energy efficiency may be improved and power consumption may be reduced compared to memory devices according to the related art.

According to an example of the disclosed technology, in the write operation of the memory device 100a of FIG. 4, the second data expressed as 011 may be received, and the logic value “m” and the logic value “l” may be written to and stored in the first memory cell M1 and the second memory cell M2, respectively. That is, according to an example, the memory device 100, 100a may receive information in a binary information system and may store the information therein in a ternary information system through the write operation.

The number of memory cells, Mₜₑᵣ, of the memory device 100 may be a natural number satisfying Equation 1 described above with respect to the number of binary bits “n” of the second data. Therefore, the memory device 100a of FIG. 4 may require only two ternary memory cells for three binary bit numbers. Therefore, according to an example of the disclosed technology, the number of memory cells may be reduced compared to a memory device that requires three binary memory cells for three binary bit numbers according to the related art so that a highly integrated memory device may be implemented.

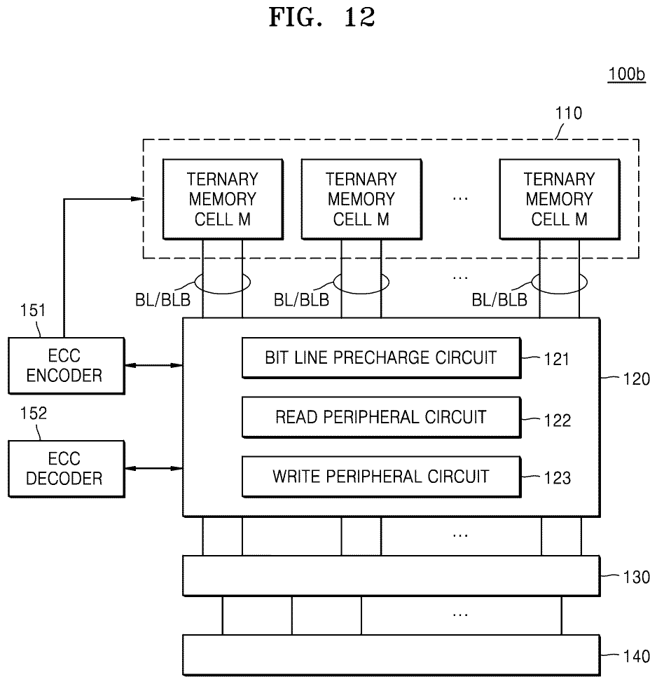

FIG. 12 illustrates a memory device 100b according to another example of the disclosed technology.

Referring to FIG. 12, the memory device 100b may further include an error correction code (ECC) encoder 151, which generates ECC information to be stored together with the first data, and an ECC decoder 152, which checks for errors in the first data based on the ECC information. The ECC information may be used to detect and correct errors during processes of reading data from and writing data to a memory cell.

In the write mode of the memory device 100b of FIG. 12, the bit line peripheral circuitry 120 may store the ECC information, which is generated by the ECC encoder 151, when storing the first data in a ternary memory cell. In the read mode of the memory device 100b of FIG. 12, the bit line peripheral circuitry 120 may transmit the ECC information, which is included in the first data, to the ECC decoder 152 when reading the first data. The process of detecting and correcting errors by using the ECC information may be the same as that of already known binary memory devices, and thus, detailed descriptions thereof are omitted. Therefore, according to an example, the memory device 100, 100a, 100b may be fully compatible with existing binary memory-based ECC by utilizing the characteristic that the information of a bit line pair changes bit-by-bit.

According to an example, a memory device may include a ternary memory cell that stores data having a ternary information system, thereby reducing the total number of memory circuits and improving area efficiency compared to binary memory cells.

According to an example, a memory device may improve energy efficiency in a read operation or a write operation by using a state, in which the initial voltage of a bit line pair in a standby mode is maintained, as a state expressing one logic value in a read mode or a write mode.

According to an example, a memory device may include a code converter that enables a memory cell, which stores data in a ternary information system, to be compatible with input data and output data each having a binary information system, thereby enabling effective interoperability with other circuits using a binary information system.

The scope of the present disclosure is not limited by these effects.

Each of the examples described above can be implemented independently, but it should be noted that the structure of each example may be applied in combination and subcombination with features of other examples.

Although the disclosed technology has been described with reference to the examples shown in the drawings, these are merely exemplary, and those skilled in the art will, in view of the benefit of the present disclosure, understand that various modifications can be made in the examples and equivalent other examples can be inferred therefrom. Therefore, the technical scope of the claimed subject matter defined by the language and spirit of the appended claims.

The particular implementations described herein are illustrative examples of the disclosed technology and are not intended to otherwise limit the scope of the claimed subject matter in any way. Moreover, no component or element is essential to implementations of the disclosed technology unless the component or element is specifically described as “essential” or “critical.”

The use of the terms “a”, and “an” and “the” and similar referents in the context describing examples (especially in the context of the following claims) are to be construed to cover both the singular and the plural. Furthermore, recitation of ranges of values herein are merely intended to serve as a shorthand method of referring individual to each separate value falling within the range, unless otherwise indicated herein, and each separate value is incorporated into the specification as if it were individually recited herein. Also, the steps of all methods described herein can be performed in any suitable order unless otherwise indicated herein or otherwise clearly contradicted by context. Examples are not limited to the described order of the steps. The use of any and all examples or exemplary language provided herein is intended merely to describe representative examples and does not pose a limitation on the scope of claimed subject matter unless otherwise claimed. Numerous modifications and adaptations will be readily apparent to one of ordinary skill in the relevant art having the benefit of the present disclosure, without departing from the spirit and scope of claims. I therefore claim as my invention all that comes within the scope of these claims and their equivalents.

What is claimed is:

1. A memory device comprising:
a memory cell array including at least two ternary memory cells each connected to a word line and a bit line pair including a bit line and an inverted bit line, the at least two ternary memory cells each storing first data having a ternary information system;
bit line peripheral circuitry connected to each of the at least two ternary memory cells through the bit line pair, the bit line peripheral circuitry configured to read 1st′ data corresponding to a voltage value of the bit line pair corresponding to the first data stored in the memory cell array in a read mode and configured to write and store the first data corresponding to the 1st′ data corresponding to the voltage value of the bit line pair in the memory cell array in a write mode; and
a code converter connected to the bit line peripheral circuitry, the code converter configured to receive the 1st′ data corresponding to the voltage value of the bit line pair from the bit line peripheral circuitry and convert the 1st′ data into second data having a binary information system in the read mode and configured to receive the second data, convert the second data into the 1st′ data corresponding to the voltage value of the bit line pair, and transmit the 1st′ data to the bit line peripheral circuitry in the write mode.

2. The memory device of claim 1, wherein:
a number of the at least two ternary memory cells, Mₜₑᵣ, is a natural number satisfying
$${M}_{ter} = \frac{2}{3} * [ {2}^{n} + \{ 1 + \frac{1 + {( - 1 )}^{n}}{2} \} ]$$
with respect to a number of binary bits, “n”, of the second data.

3. The memory device of claim 1, wherein the bit line peripheral circuitry includes:
a bit line precharge circuit configured to precharge the bit line pair to an initial voltage in a standby mode.

4. The memory device of claim 3, wherein the bit line peripheral circuitry includes:
a read peripheral circuit configured to, in the read mode, read a state, in which the initial voltage of the bit line pair is maintained, or a state, in which the initial voltage of one of the bit line and the inverted bit line in the bit line pair is changed, according to the first data stored in a selected one of the at least two ternary memory cells and generate the 1st′ data corresponding to the voltage value of the bit line pair.

5. The memory device of claim 4, wherein:
the first data corresponds to one of a first logic value, a second logic value, and a third logic value,
the first logic value corresponds to the state in which the initial voltage of one of the bit line and the inverted bit line in the bit line pair is changed,
the second logic value corresponds to the state in which the initial voltage of the bit line pair is maintained, and
the third logic value corresponds to a state in which the initial voltage of the other one of the bit line and the inverted bit line in the bit line pair is changed.

6. The memory device of claim 4, wherein:
the 1st′ data has one of a 1st′ logic value, a 2nd′ logic value, and a 3rd′ logic value, each of the 1st′ logic value, the 2nd′ logic value, and the 3rd′ logic value having the binary information system in correspondence to a change or maintenance of the initial voltage of the bit line pair.

7. The memory device of claim 3, wherein the bit line peripheral circuitry includes:
a write peripheral circuit configured to write the first data to a selected one of the at least two ternary memory cells in the write mode by maintaining the initial voltage of the bit line pair or changing the initial voltage of one of the bit line and the inverted bit line in the bit line pair, based on the 1st′ data received from the code converter.

8. The memory device of claim 7, wherein:
the first data has one of a first logic value, a second logic value, and a third logic value, the first logic value corresponding to the state in which the initial voltage of one of the bit line and the inverted bit line in the bit line pair is changed,
the second logic value corresponds to the state in which the bit line pair is maintained at a precharge voltage, and
the third logic value corresponds to a state in which the initial voltage of the other one of the bit line and the inverted bit line in the bit line pair is changed.

9. The memory device of claim 7, wherein:
the 1st′ data has one of a 1st′ logic value, a 2nd′ logic value, and a 3rd′ logic value; and
each of the 1st′ logic value, the 2nd′ logic value, and the 3rd′ logic value has the binary information system in correspondence to a change or maintenance of the initial voltage of the bit line pair.

10. The memory device of claim 1, wherein each of the at least two ternary memory cells includes:
a first inverter and a second inverter cross-connected to a first node and a second node and respectively including a P-channel transistor and an N-channel transistor, the first node having a voltage corresponding to the first data, and the second node having an inverted voltage of the voltage of the first node or a same voltage as the first node;
a first access transistor having an end connected to the first node, an opposite end connected to one of the bit line and the inverted bit line in the bit line pair, and a control terminal connected to the word line; and
a second access transistor having an end connected to the second node, an opposite end connected to the other one of the bit line and the inverted bit line in the bit line pair, and a control terminal connected to the word line.

11. The memory device of claim 10, wherein each of the at least two ternary memory cells further includes:
a first transistor having an end connected to a read-only word line, an opposite end connected to a read-only bit line, and a control terminal connected to the first node; and
a second transistor having an end connected to the read-only word line, an opposite end connected to a read-only inverted bit line, and a control terminal connected to the second node.

12. The memory device of claim 1, further comprising:
an error correction code (ECC) encoder configured to generate ECC information to be stored together with the first data; and
an ECC decoder configured to check for errors in the first data, based on the ECC information,
wherein, in the write mode, the bit line peripheral circuitry is further configured to store the ECC information when storing the first data in the memory cell array, and
in the read mode, the bit line peripheral circuitry is further configured to transmit, to the ECC decoder, the ECC information included in the first data when reading the first data.

13. The memory device of claim 1, further comprising:
an input/output (I/O) interface configured to input or output the second data having the binary information system,
wherein the code converter is further configured to transmit the second data to the I/O interface in the read mode and receive the second data from the I/O interface in the write mode.
